(19) United States
(12) Patent Application Publication
(10) Pub. No.: US 2008/0302761 A1
(43) Pub. Date: Dec. 11, 2008

(54) PLASMA PROCESSING SYSTEM AND USE THEREOF

(75) Inventors: Masaki Hirayama, Miyagi (JP); Tadahiro Ohmi, Miyagi (JP)

Correspondence Address: OBLON, SPIVAK, MCCLELLAND MAIER & NEUSTADT, P.C., 1940 DUKE STREET, ALEXANDRIA, VA, 22314, US

(73) Assignees: TOKYO ELECTON LIMITED, Tokyo (JP); Tohoku University, Sendai-shi (JP)

(21) Appl. No.: 12/137,088

(22) Filed: Jun. 11, 2008

(30) Foreign Application Priority Data
Jun. 11, 2007 (JP) 2007-153552

(51) Int. Cl. C23F 1/02; C23C 16/513; H05H 1/46

(52) U.S. Cl. 216/67; 118/723 R; 427/569; 134/1.1; 156/345.35

(57) ABSTRACT

A plasma processing system 10 includes a processing chamber 100, a microwave source 700 that outputs a microwave, a coaxial waveguide 315 that transfers the microwave from the microwave source, a plurality of dielectric plates 305 that transmit the microwave transferred through the coaxial waveguide 315 and discharge the microwave into the processing chamber 100, and a metal electrode 310 having a first end and a second end, the first end coupled to the coaxial waveguide 315, the second end disposed on the surface of the dielectric plate 305 facing the substrate. The coaxial waveguide 315 holds the dielectric plate 305 and metal electrode 310 and is securely fastened by a fastening mechanism 500. The coaxial waveguide 315 is given a force by the spring member 515, the force being directed away from the processing chamber 100.

### CROSS-REFERENCE TO RELATED APPLICATION

The present invention contains subject matter related to Japanese Patent Application JP 2007-153552, filed in the Japan Patent Office on Jun. 11, 2007, the entire contents of which being incorporated herein by reference.

### FIELD OF THE INVENTION

The present invention relates to a plasma processing system that excites a gas using an electromagnetic wave and applies a plasma process to a target object, and more particularly, to a method of fastening a dielectric material.

### BACKGROUND OF THE INVENTION

Plasma processing systems needs power to excite a gas supplied in the processing chambers to generate the plasma. A dielectric plate is generally used to supply power to the processing chamber. An example plasma processing system includes an upper electrode and a lower electrode opposed to each other in the processing chamber. The upper electrode is applied with a high-frequency electric power to ionize a process gas into a plasma in the processing chamber. A plasma process is thus applied to a substrate mounted on the lower electrode.

The upper electrode includes a stack of upper members, cooling plates, and electrode plates, the electrode plates including dielectric materials. Between these elements and the processing chamber, is provided support members to support the elements.

Each cooling plate has a plurality of through-holes formed thereon. Screws are inserted through the through-holes and screwed in screw holes on one of the electrode plates. The cooling plates and the electrode plates are thus firmly joined.

### SUMMARY OF THE INVENTION

Unfortunately, the above configuration may provide a gap between the electrode plate and the support member. The plasma may enter the gap, causing an abnormal discharge. The electromagnetic wave power is originally to be used for the generation of the plasma. The power, however, may be wasted due to the discharge. An O-ring is provided between the electrode plate and the support member to vacuum-seal therebetween. The discharge may damage the O-ring. Heat from the discharge may generate cracks of the electrode plates including dielectric materials. It is costly to accurately machine the electrode plates and the support members to decrease the gap therebetween. These elements may accurately be machined to provide a sufficiently small gap. When, however, the electrodes are exposed to the plasma and increased in temperature, thermal expansion difference between the elements may increase the gap, causing the abnormal discharge or may decrease the gap, applying a high stress between the elements that causes cracks between them.

To solve the issues, an aspect of the present invention provides a plasma processing system that excites a gas using an electromagnetic wave and applies a plasma process to a target object, the system including: a processing chamber; an electromagnetic source that outputs an electromagnetic wave; a dielectric plate on the inner wall of the processing chamber, the dielectric plate transmitting the electromagnetic wave into the processing chamber; a conductor rod adjacent to the dielectric plate, the conductor rod transferring the electromagnetic wave to the dielectric plate; a metal electrode coupled to the conductor rod to hold the dielectric plate; and a device to give the conductor rod a force directed away from the processing chamber.

The dielectric plate may thus be held by the metal electrode coupled to the conductor rod and raised away from the processing chamber by a force given to the conductor rod. The dielectric plate may thus be brought into close contact with the inner wall of the processing chamber with a moderate force against the external pressure (atmospheric pressure) to move the dielectric plate away from the inner wall of the processing chamber. This may reduce the abnormal discharge caused by the plasma near the dielectric plate entering the gap between the inner wall of the processing chamber and the dielectric plate. An uniform and stable plasma may thus be generated.

To solve the issues, another aspect of the present invention provides a method of using a plasma processing system, the method including: outputting an electromagnetic wave at a frequency of 1 GHz or less from an electromagnetic source; transferring the electromagnetic wave to a conductor rod, the conductor rod being raised by a device to give the conductor rod a force directed away from a processing chamber, the conductor rod being coupled to a metal electrode to hold a dielectric plate; transferring the electromagnetic wave transferred through the conductor rod to the dielectric plate adjacent to the conductor rod; and exciting a process gas using the electromagnetic wave transmitted by the dielectric plate and introduced into the processing chamber and applying a desired plasma processing to a target object.

This may support the dielectric plate with the metal electrode and the conductor rod coupled to the metal electrode and raise the conductor rod with the spring member. This may bring the dielectric plate into the close contact with the inner wall of the processing chamber, and apply the plasma processing to the target object.

To solve the issues, another aspect of the present invention provides a method of cleaning a plasma processing system, the method including: transferring the electromagnetic wave to a conductor rod raised by a device to give the conductor rod a force directed away from a processing chamber, the conductor rod being coupled to a metal electrode to hold a dielectric plate; transferring the electromagnetic wave transferred through the conductor rod to the dielectric plate adjacent to the conductor rod; and exciting a cleaning gas using the electromagnetic wave transmitted by the dielectric plate and introduced into the processing chamber and cleaning the plasma processing system.

Therefore, an electromagnetic wave at 1 GHz or less, for example, may be used to excite the uniform and stable plasma from a single F-based gas. The single F-based gas may not be effective in exciting the uniform and stable plasma with a certain degree of power of an electromagnetic wave at a frequency of 2.45 GHz because the power may not spread the surface wave. Power of a practical electromagnetic wave may thus be used to excite a cleaning gas to generate a plasma. The plasma may clean the interior of the plasma processing system.

### BRIEF DESCRIPTION OF THE DRAWINGS

FIG. 1 is a vertical cross-sectional view of a plasma processing system according to a first embodiment of the present invention.

FIG. 2 illustrates the ceiling surface of the plasma processing system in the first embodiment.

FIG. 3 shows the vicinity of a spring member in the first embodiment.

FIG. 4 is a vertical cross-sectional view of a plasma processing system according to a second embodiment of the present invention.

FIG. 5 shows the vicinity of a spring member in the second embodiment.

FIG. 6 is an enlarged view of a coupling portion in the second embodiment.

FIG. 7 is an enlarged view of a coupling portion in a modification 1 of the second embodiment.

FIG. 8 is an enlarged view of a coupling portion in a modification 2 of the second embodiment.

FIG. 9 shows another modification of the system.

FIG. 10 shows the cross-sectional view taken along the line X-X in FIG. 9.

FIG. 11 shows a profile of microwave power density versus plasma electron density.

FIG. 12 shows another modification of the system.

### DESCRIPTION OF THE EMBODIMENTS

### First Embodiment

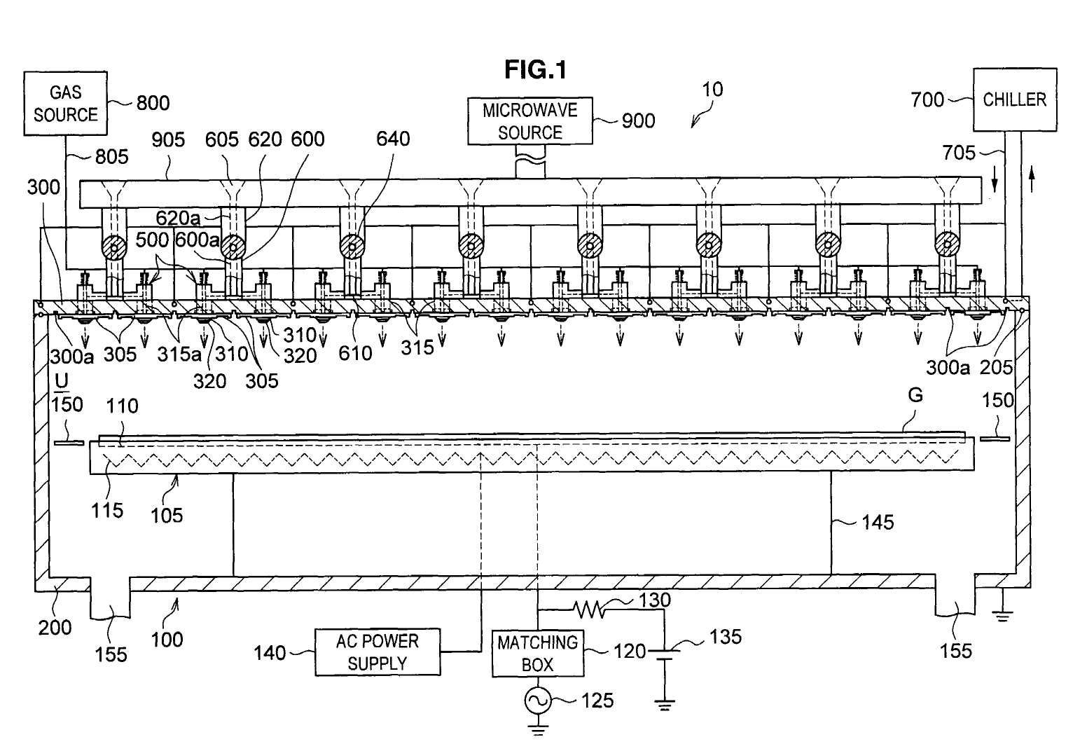

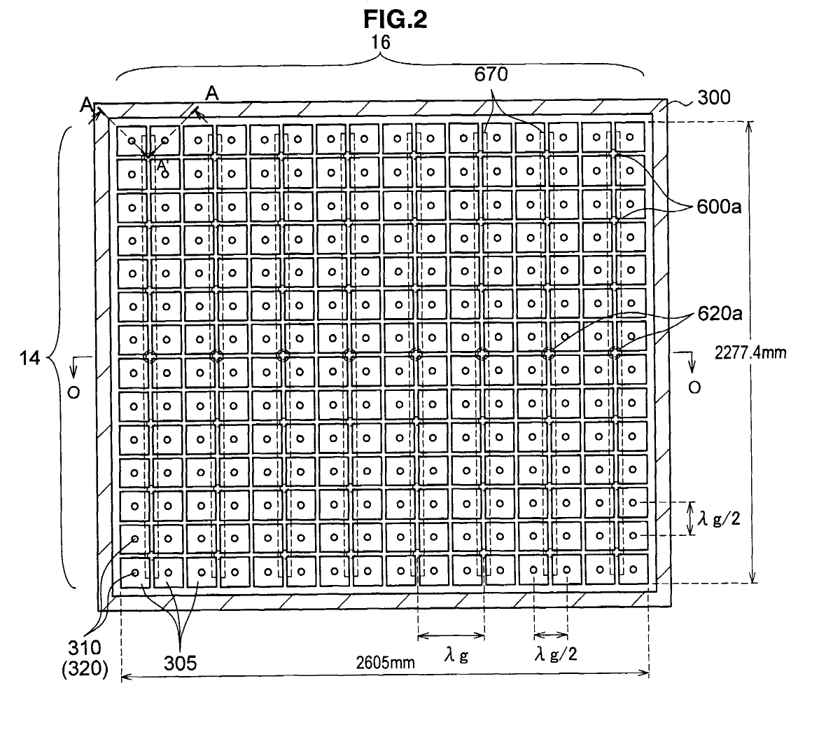

With reference to FIGS. 1 and 2, a plasma processing system according to a first embodiment of the present invention will be described below. FIG. 1 schematically shows a vertical cross-sectional view of the system (a cross-section taken along the O-O in FIG. 2). FIG. 2 shows the ceiling surface of the processing chamber. Note that, in the following discussion and accompanying drawings, the elements having the same configuration and function are provided with the same reference symbol and their description are omitted.

### (Configuration of Plasma Processing System)

A plasma processing system 10 includes a processing chamber 100 in which a plasma process is applied to a glass substrate (“substrate G”). The processing chamber 100 includes a chamber main portion 200 and a lid 300. The chamber main portion 200 has a bottom-closed cube shape with an opening formed on the top thereof. The opening is closed by the lid 300. On the contact surface between the chamber main portion 200 and the lid 300 is provided with an O-ring 205. The O-ring 205 seals the chamber main portion 200 and the lid 300 and thus forms a processing chamber U. The chamber main portion 200 and the lid 300 are made of, for example, metal such as aluminum. They are electrically grounded.

The processing chamber 100 contains a susceptor 105 (stage) to support the substrate G. The susceptor 105 is made of, for example, aluminum nitride. The susceptor 105 contains a power feeding portion 110 and a heater 115.

The power-feeding portion 110 is connected to a high-frequency power supply 125 via a matching box 120 (such as a capacitor). The power-feeding portion 110 is also connected to a high-voltage dc power supply 135 via a coil 130. The high-frequency power supply 125 and the high-voltage dc power supply 135 are grounded.

The power-feeding portion 110 uses high-frequency electric power from the high-frequency power supply 125 to apply a predetermined bias voltage into the processing chamber 100. The power-feeding portion 110 uses dc voltage from the high-voltage dc power supply 135 to electrostatically chuck the substrate G.

The heater 115 is connected to an AC power supply 140 outside the processing chamber 100. The heater 115 uses AC voltage from the AC power supply 140 to keep the substrate G at a predetermined temperature. The susceptor 105 is supported by a support member 145. The susceptor 105 is surrounded by a baffle plate 150 to control the gas flow in the processing chamber U to the preferable state.

At the bottom of the processing chamber 100 is provided a gas exhaust pipe 155. Outside the processing chamber 100 is provided a vacuum pump (not shown). The vacuum pump exhausts gases from the processing chamber 100 through the gas exhaust pipe 155. The processing chamber U is thus evacuated to a desired degree of vacuum.

On the lid 300 are provided a plurality of dielectric plates 305, a plurality of metal electrodes 310, and a plurality of inner conductors 315a of coaxial waveguides. With reference to FIG. 2, each dielectric plate 305 is a generally square plate of 148 mm×148 mm and made of alumina (Al₂O₃). The dielectric plates 305 are arranged in a matrix at regular intervals of an integral multiple (here, once) of λg/2. The λg is the guided wavelength of a coaxial waveguide divider 670 (the λg is 328 mm at 915 MHz). The dielectric plates 305 of 224 (=14×16) are thus uniformly disposed on the ceiling surface of 2277.4 mm×2605 mm of the processing chamber 100.

Each dielectric plate 305 has a symmetrical shape and may thus easily generate an uniform plasma therein. The dielectric plates 305 are disposed at regular intervals of an integral multiple of λg/2. The inner conductors 315a of the coaxial waveguides may therefore be used to introduce an electromagnetic wave to generate an uniform plasma.

Returning to FIG. 1, the metal surface of the lid 300 has a groove 300a formed thereon. The groove 300a may reduce the propagation of the conductor surface wave. Note that the conductor surface wave is a wave that propagates between the metal surface and a plasma.

Each inner conductor 315a passes through the dielectric plate 305 and has a metal electrode 310 at the end. The metal electrode 310 is exposed to the substrate G. The inner conductor 315a and the metal electrode 310 hold the dielectric plate 305. The surface of the metal electrode 310 facing the substrate is provided with a dielectric cover 320. The cover 320 may reduce the electric field concentration.

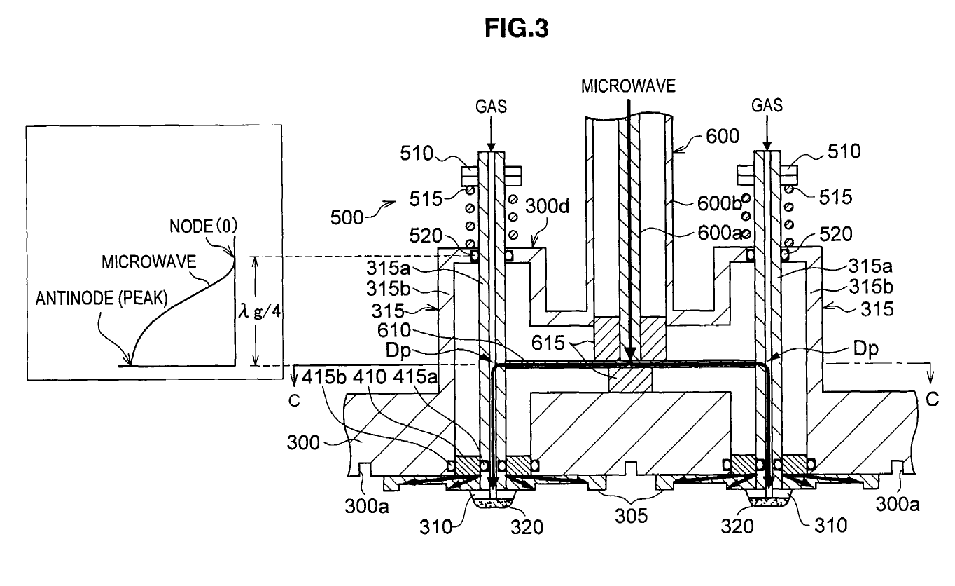

FIG. 3 shows the cross-sectional view taken along the line A-A′-A in FIG. 2. The coaxial waveguide 315 includes the cylindrical inner conductor (shaft) 315a and an outer conductor 315b. The tube 315 is made of metal (preferably copper). The inner conductor 315a is an example of the conductor rod. Between the lid 300 and the inner conductor 315a is provided a dielectric ring 410. The dielectric 410 has a center through which the inner conductor 315a passes. The dielectric ring 410 has an inner surface and a peripheral surface. The inner surface has an O-ring 415a thereon. The peripheral surface has an O-ring 415b thereon. The O-rings 415a and 415b may vacuum-seal the processing chamber U.

The inner conductor 315a passes through a lid portion 300d and out of the processing chamber 100. The inner conductor 315a is fastened by a fastening mechanism 500. The mechanism 500 includes a coupling portion 510, a spring member 515, and a shorting portion 520. The fastening mechanism 500 uses elastic force of the spring member 515 to raise the inner conductor 315a away from the processing chamber 100. Note that the lid portion 300d is a portion that resides on the upper surface of the lid 300 and is integrated with the lid 300 and the outer conductor 315b.

The shorting portion 520 resides at the portion of the coaxial waveguide 315 through which the inner conductor 315a passes. The shorting portion 520 electrically short-circuits the inner conductor 315a of the coaxial waveguide 315 and the lid portion 300d. The shorting portion 520 includes a shield spiral that allows the inner conductor 315a to slide vertically. The shorting portion 520 may also include a metal brush.

Heat flows into the metal electrode 310 from the plasma. The shorting portion 520 and the inner conductor 315a may efficiently release the heat to the lid. This may reduce the heating of the inner conductor 315a, thereby reducing the degradation of the O-rings 415a and 415b adjacent to the inner conductor 315a. The shorting portion 520 may also reduce the transfer of the microwave to the spring member 515 via the inner conductor 315a. This may reduce the abnormal discharge or power loss near the spring member 515. The shorting portion 520 may also reduce the shaft swing of the inner conductor 315a and thus securely hold the conductor 315a.

An O-ring (not shown) may reside between the lid portion 300d and the inner conductor 315a at the shorting portion 520 and between a dielectric material 615 (described below) and the lid portion 300d to vacuum-seal therebetween. An inert gas may then be filled in the space of the lid portion 300d to reduce the introduction of the atmosphere impurities into the processing chamber.

In FIG. 1, a chiller 700 is connected to a coolant pipe 705. The coolant from the chiller 700 circulates in the coolant pipe 705 and back to the chiller 700, thus keeping the processing chamber 100 at a desired temperature. A gas source 800 supplies a gas through a gas line 805. The gas is then introduced into the processing chamber via the gas flow channel in the inner conductor 315a shown in FIG. 3.

Two microwave sources 900 each output a microwave of 120 kW (=60 kW×2 (2 W/cm²)). The microwave is supplied into the processing chamber through the dielectric plates 305 after transferred through the following components: a waveguide divider 905, eight coaxial to waveguide adapters 605, eight coaxial waveguides 620, the eight coaxial waveguide dividers 670 (see FIG. 2) disposed in parallel on the backside of the system 10 in FIG. 1, coaxial waveguides 600 coupled to the coaxial waveguide dividers 670 (seven tubes 600 to each tube 670), a split plate 610, and the coaxial waveguide 315. After discharged into the processing chamber U, the microwave excites the process gas from the gas source 800. The resulting plasma is used to carry out a desired plasma process on the substrate G.

### (Method of Fastening Dielectric Plate)

A method of fastening the dielectric plate will be described in more detail. With reference to FIG. 3, the inner conductor 315a is coupled to the metal electrode 310 via the dielectric plate 305. The conductor 315a projects out of the processing chamber 100 and is fastened by the fastening mechanism 500.

The spring member 515 of the fastening mechanism 500 resides around the inner conductor 315a. The member 515 has opposite ends securely fastened to the lid portion 300d of the processing chamber 100 and the coupling portion 510, respectively. Using the spring's elastic force, the spring member 515 gives a force directed away from the processing chamber 100 to the inner conductor 315a.

The spring member 515 may thus raise the inner conductor 315a and the dielectric plate 305 held by the metal electrode 310 with a constant force. The spring member 515 is used to raise these components to reduce the extension and cracks of the dielectric plate 305 and the abnormal discharge in a gap generated between the dielectric plate 305 and the inner wall of the processing chamber. The extension and cracks and the gap are caused by the thermal expansion coefficient differences between the inner conductor 315a, the metal electrode 310, and the dielectric plate 305.

### (Shorting Portion)

The shorting portion 520 includes a shield spiral. The portion 520 electrically short-circuits the inner conductor 315a and the lid portion 300d. The portion 520 also releases the heat of the inner conductor 315a to the grounded processing chamber 100. The shorting portion 520 may include a metal coil or a metal brush.

Heat flows into the metal electrode 310 from the plasma. The shorting portion 520 and the inner conductor 315a may efficiently release the heat to the lid. This may reduce the heating of the inner conductor 315a, thereby reducing the degradation of the O-rings 415a and 415b adjacent to the inner conductor 315a. The shorting portion 520 reduces the transfer of the microwave to the spring member 515 through the inner conductor 315a. This may reduce the abnormal discharge and power loss around the spring member 515. The shorting portion 520 may also securely hold the inner conductor 315a and reduce its shaft swing.

The split plate 610 and the inner conductor 315a are connected at a position Dp. The microwave transferred through the inner conductor 315a has a guided wavelength λ g. The interval between the Dp and the shorting portion 520 is designed to be λ g/4. With reference to the left side of FIG. 3, when a peak (antinode) of the microwave is placed at the position Dp, the power of the microwave at the shorting portion 520 becomes zero (node). The portion between the shorting portion 520 and the position Dp may be regarded as a distributed constant line with one end short-circuited. The distributed constant line with one end short-circuited and having a length of λ g/4 has impedance of almost infinity when viewed from the other end. This means that the portion between the position Dp and the shorting portion 520 does not exist with respect to the microwave. This may facilitate the design of the transmission line.

According to the above configuration, the microwave transferred to the coaxial waveguide 600 is divided into a plurality of microwaves via the split plate 610. The microwaves are then transferred to the respective inner conductors 315a and transferred to the respective dielectric plates 305. There are 224 of the dielectric plates 305 uniformly disposed on the ceiling surface. The microwave is thus supplied into the processing chamber from the dielectric plates 305 with the power equally distributed. The microwave may thus be supplied at a low frequency. The use of the coaxial waveguide to hold the dielectric plate 305 may facilitate the design of the lower portion of the lid 300.

The inner conductor 315a holds the dielectric plate 305 and is raised away from the processing chamber 100 by the elastic force of the spring member 515. The dielectric plate 305 may thus be brought into close contact with the inner wall of the processing chamber 100 with a moderate force. This may reduce the abnormal discharge caused by the plasma entering the gap between the inner wall 300 of the processing chamber and the dielectric plate 305. The uniform and stable plasma may thus be generated.

For processing of a large-area substrate G, the dielectric plate 305 provided on the ceiling of the processing chamber 100 should be enlarged accordingly. In the plasma processing system 10 in this embodiment, a large number of dielectric plates 305 are disposed on the whole ceiling surface, and the dielectric plates 305 are raised by a large number of spring members. This may provide a simple structure around the lid, which is advantageous in cost and maintenance. The system 10 may also correspond to a large-area substrate G only by changing the number of dielectric plates 305. The system 10 thus has a high extensibility and easy maintenance.

The spring member 515 is an example of a first spring member. The member 515 may be, for example, a coiled spring or a plate spring washer. The spring member 515 may also be either a metal spring or a ceramic spring. These elements' elastic force may raise the inner conductor 315a of the coaxial waveguide 315 away from the processing chamber 100.

### Second Embodiment

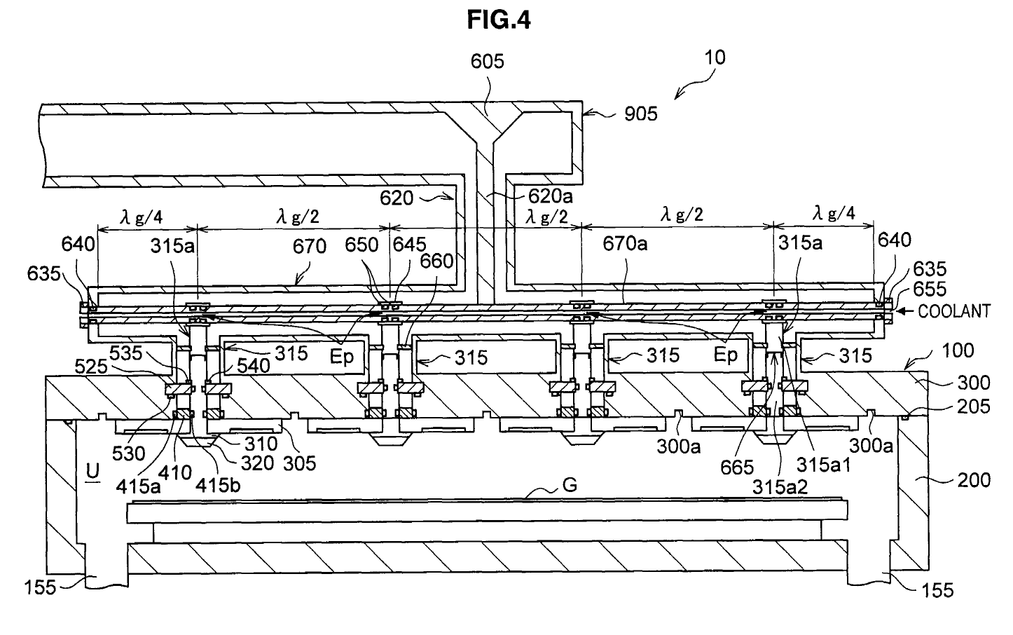

With reference to FIGS. 4, 5 and 6, a plasma processing system 10 in a second embodiment will be described below. The plasma processing system 10 in the second embodiment differs from the plasma processing system 10 in the first embodiment as follows. In the first embodiment, the dielectric plate 305 is raised by the spring member 515. In the second embodiment, the dielectric plate 305 is held by the inner conductor 315a of the coaxial waveguide and the metal electrode 310 and is raised by the O-ring 530. Focusing on this difference, the plasma processing system 10 according to this embodiment will be described below.

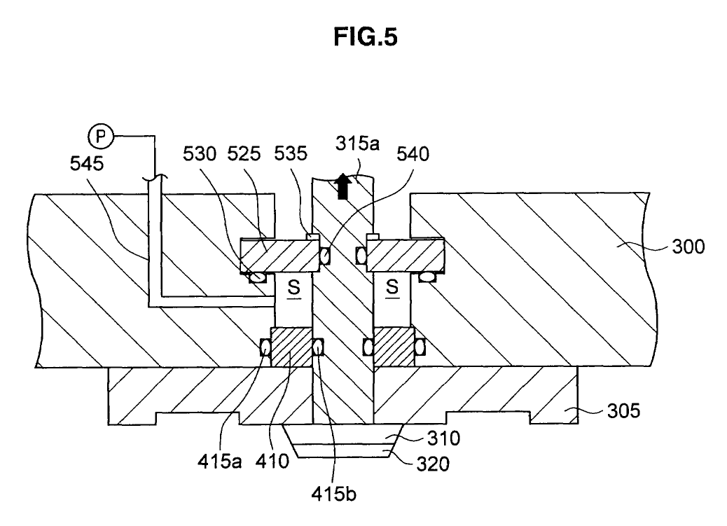

Between the lid 300 and the inner conductor 315a, are provided the dielectric ring 410 and the O-rings 415a and 415b. The O-rings 415a and 415b reside on the outer and inner surfaces of the ring material 410, respectively. The O-rings 415a and 415b vacuum-seal the processing chamber. With reference to the enlarged view of FIG. 5, in this embodiment, the inner conductor 315a passes through a dielectric ring 525. The ring material 525 has an outer surface and an inner surface that are embedded in the lid 300 (lid portion 300d).

On the outer side of the surface of the dielectric ring 525 that faces the dielectric plate 305, is provided the O-ring 530. The O-ring 530 serves to raise the inner conductor 315a. In this embodiment, the O-ring 530 above the dielectric material 410 serves as a spring member. If the inner conductor 315a is extended by the thermal expansion, the inner conductor 315a may be raised by the repulsive force of the O-ring 530 with a moderate force.

On the inner side of the top surface of the dielectric ring 525, is provided a cushion ring 535. The ring 535 may buffer a local force that is applied to the dielectric material 525 when the inner conductor 315a is raised. The cushion ring 535 is preferably made of a somewhat soft material that has a buffering effect and low dielectric loss not to be overheated by the absorbed electromagnetic wave. In this embodiment, the cushion ring 535 is made of Teflon (registered trademark). Between the dielectric ring 525 and the inner conductor 315a, is provided an O-ring 540. The O-ring 540 seals between the dielectric ring 525 and the inner conductor 315a.

Between the dielectric ring 410 and the dielectric ring 525, is provided a space S. A evacuation pipe 545 connected to a vacuum pump P communicates with the space S. The space S may thus be evacuated to a desired degree of vacuum. Evacuating the space S may significantly reduce the amount of impurity gases transmitted into the processing chamber through the O-rings 410 and 415a. This may increase the cleanliness of the processing chamber. After the space S is evacuated, an inert gas such as Argon may be filled in the space S through the evacuation pipe 545.

With reference to FIG. 4, the coaxial waveguide divider 670 contains an inner conductor 670a. The conductor 670a suspends the four inner conductors 315a disposed in a matrix at intervals of generally n₁×λ g/2 (here n₁=1). The dielectric plate thus has substantially the same horizontal and vertical size. This may increase the symmetry of the surface wave propagation mode. An uniform plasma may thus be easily obtained in the surface of the dielectric plate.

The inner conductor 670a of the coaxial waveguide divider 670 is securely fastened at both ends by fasteners 635. The fasteners 635 determine the position of the inner conductor 670a in the axis direction. At each portion of the coaxial waveguide divider 670 through which the conductor 670a passes, is provided a shorting portion 640. The portions 640 electrically short-circuit the inner conductor 670a of the coaxial waveguide divider 670 and the outer frame (the lid portion 300d).

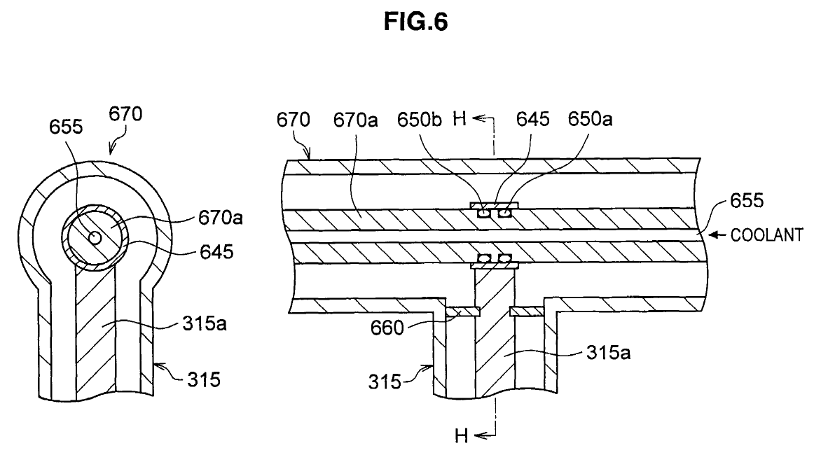

FIG. 6 shows an enlarged view of a portion of the coaxial waveguide divider 670 on the right, and a cross-sectional view taken along the line H-H on the left. The inner conductor 670a of the coaxial waveguide divider 670 connects to a cylindrical connector 645. The connector 645 has an inner surface provided with two shield spirals 650a and 650b. The spirals 650a and 650b allow the inner conductor 670a to slide laterally. The inner conductor 670a may slide in response to heat stress, thereby reducing the stress applied to the transmission line.

### (Cooling Mechanism)

The inner conductor 670a has a passage 655 passing therethrough. The passage 655 serves to flow a coolant. The passage 655 is coupled to the coolant pipe 705. The coolant through the coolant pipe 705 from the chiller 700 circulates in the passage 655. The cooling mechanism may also be provided in the inner conductor 315a. This may reduce the overheating of the inner conductor 670a and the inner conductor 315a. The inner conductor 315a has a holding portion 660 provided thereto to hold the inner conductor 315a. The holding portion 660 is formed as a ring and made of Teflon (registered trademark).

With reference to FIG. 4, the inner conductor 315a includes an upper inner conductor 315a1, a lower inner conductor 315a2, and a connector 665 coupling the conductors. The connector 665 may electrically connect the upper inner conductor 315a1 and the lower inner conductor 315a2. The connector 665 may also reduce the stress due to the thermal expansion difference between the inner conductor 315a and the members therearound.

The plasma processing system in the second embodiment may give a force to the coaxial waveguide 315 from the inside of the processing chamber 100, the force being directed away from the processing chamber 100. This may bring the dielectric plate 305 held by the metal electrode 310 into close contact with the inner wall of the processing chamber 100.

The dielectric ring 525 is an example of a first dielectric member. The O-ring 530 is an example of a second spring member that resides between the dielectric ring 525 and the processing chamber 100 and also on the bottom surface of the dielectric ring 525 (the surface facing the inside of the processing chamber). The second spring member may be an O-ring, a C-ring, a metal spring, or a ceramic spring. The spring's elastic force may thus give the inner conductor 315a a force directed away from the processing chamber 100.

The cushion ring 535 is an example of a buffer member that resides between the dielectric ring 525 and the inner conductor 315a and also on the top surface of the dielectric ring 525. Local force is thus applied to the inner conductor 315a, thereby protecting the inner conductor 315a.

The O-ring 540 is an example of a first sealing member that resides between the dielectric ring 525 and the inner conductor 315a. The O-ring 540 seals between the dielectric material 525 and the conductor 315a. The second spring member and the first sealing member may include the O-ring or the C-ring to vacuum-seal between the first dielectric member and the inner conductor of the coaxial waveguide and between the first dielectric member and the lid portion 300d of the processing chamber. This may keep airtightness of the processing chamber.

The dielectric ring 410 is an example of a second dielectric member of a ring shape that resides between the dielectric ring 525 and the dielectric plate 305. The coaxial waveguide 315 passes through the dielectric material 410. The O-ring 415a is an example of a second sealing member that seals between the dielectric ring 410 and the processing chamber 100. The O-ring 415b is an example of a third sealing member that seals between the coaxial waveguide 315 or the metal electrode 310 and the dielectric ring 410.

The combination of the dielectric ring 525 and the O-rings 530 and 540, and the combination of the dielectric ring 410 and the O-rings 415a and 415b may firmly vacuum-seal between the inner conductor 315a and the processing chamber. The inner conductor 315a holds the dielectric plate 305. The dielectric material 410 and the dielectric material 525 support the inner conductor 315a at two points. This may reduce the shaft swing of the coaxial waveguide.

The first dielectric member and the second dielectric member may be made of quartz or alumina. The second spring member and the first sealing member, the second sealing member and the third sealing member may be a C-ring.

The plasma processing system 10 in the second embodiment differs from the plasma processing system 10 in the first embodiment in various things such as the number and shape of dielectric plates 305, the number and shape of metal electrodes 310, and the configuration of the transmission line. In this way, the dielectric plate 305 and the metal electrode 310 may have various numbers and shapes, and the transmission line may have various configurations.

### Modification of Second Embodiment

The modifications of the second embodiment include the following modifications 1 and 2.

### (Modification 1)

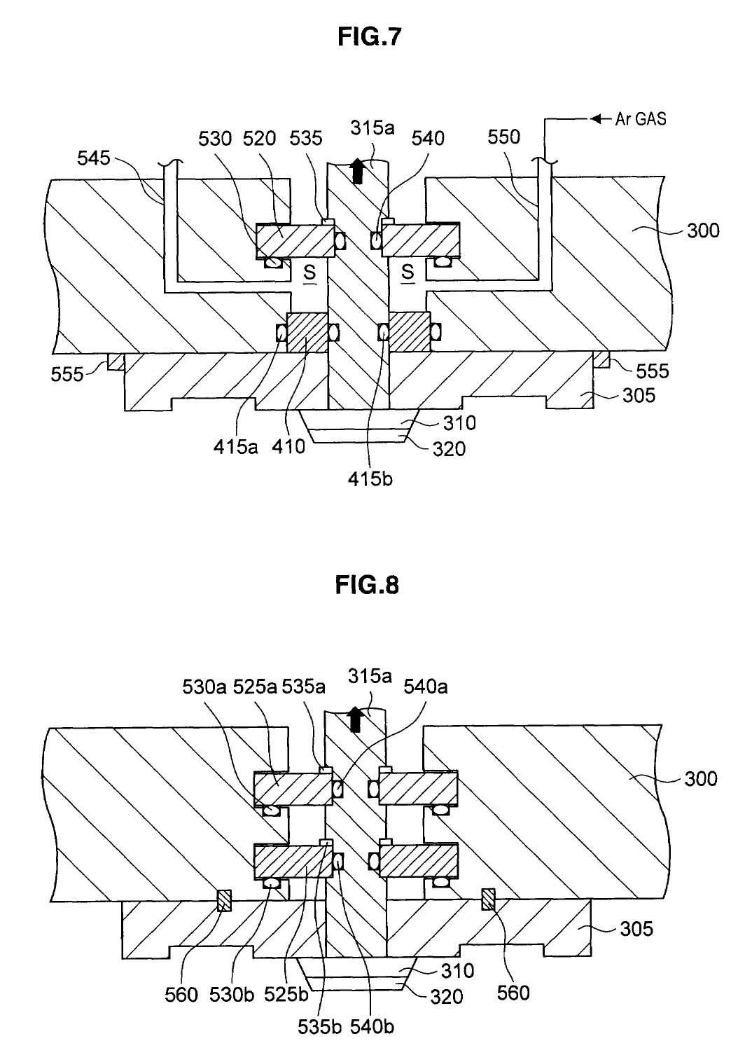

FIG. 7 shows a plasma processing system 10 in a modification 1. The system 10 in the modification 1 differs from the system 10 in the second embodiment as follows. The system 10 in the second embodiment only includes the evacuation pipe 545. In contrast, the system 10 in the modification 1 includes the evacuation pipe 545 and a gas supply pipe 550. The pipes 545 and 550 both communicate with the space S between the dielectric ring 410 and the dielectric ring 525.

Specifically, in the plasma processing system 10 in the modification 1, the gas supply pipe 550 and the evacuation pipe 545 connect to the gas source 800 and pass through the lid 300 to communicate with the space S. The gas source 800 fills an inert gas (such as an argon gas) in the space S through the gas supply pipe 550. The inert gas presses away the atmosphere in the space S through the evacuation pipe 545. The atmosphere of the space S is thus replaced by the inert gas. This may reduce the introduction of the atmosphere impurities into the processing chamber. Alternatively, the evacuation pipe 545 may be connected to a pump P, and the pump P may evacuate the space S and then the inert gas is filled in the space S through the gas supply pipe 545.

In this modification, a convex member 555 is provided adjacent to at least one side of the peripheral surface of the dielectric plate 305. The convex member 555 is an example of an engaging portion that resides between the dielectric plate 305 and the lid portion 300d and engages the dielectric plate 305 and the lid portion 300d. This may reduce the rotation of the dielectric plate 305 when the inner conductor 315a rotates around the axis, the conductor 315a being raised out of the processing chamber 100.

### (Modification 2)

FIG. 8 shows a plasma processing system 10 in a modification 2. The system 10 in the modification 2 differs from the system 10 in the second embodiment as follows. The system 10 in the second embodiment includes the combination of the dielectric ring 525, the O-rings 530 and 540, and the cushion ring 535, and the combination of the dielectric ring 410 and the O-rings 415a and 415b. These two combinations vacuum-seal between the inner conductor 315a and the processing chamber 100. In contrast, the system 10 in the modification 2 includes two combinations of the following components in a vertical direction: the dielectric ring 525, the O-rings 530 and 540, and the cushion ring 535.

These combinations may firmly vacuum-seal between the inner conductor 315a and the processing chamber 100. Additionally, the combinations guide the inner conductor 315a at two points of the dielectric ring 410 and the dielectric ring 525. This may reduce the shaft swing of the inner conductor 315a and thus bring the dielectric plate 305 into secure and close contact with the ceiling surface. This modification includes the O-rings 530a and 530b as the spring member. The inner conductor 315a may thus be raised out of the processing chamber 100 more firmly.

This modification includes an engaging portion 560 between the dielectric plate 305 and the lid 300. The engaging portion 560 engages the dielectric plate 305 and the lid 300. This may also reduce the rotation of the dielectric plate 305 around the axis of the inner conductor 315a. The engaging portion 560 may include a projection on the dielectric plate 305 and a depression on the lid 300, and vice versa. The projection and the depression may be engaged.

According to the above embodiments, the spring's elastic force may bring the dielectric plate 305 into close contact with the inner wall of the processing chamber 100. This may avoid the abnormal discharge and provide a stable plasma.

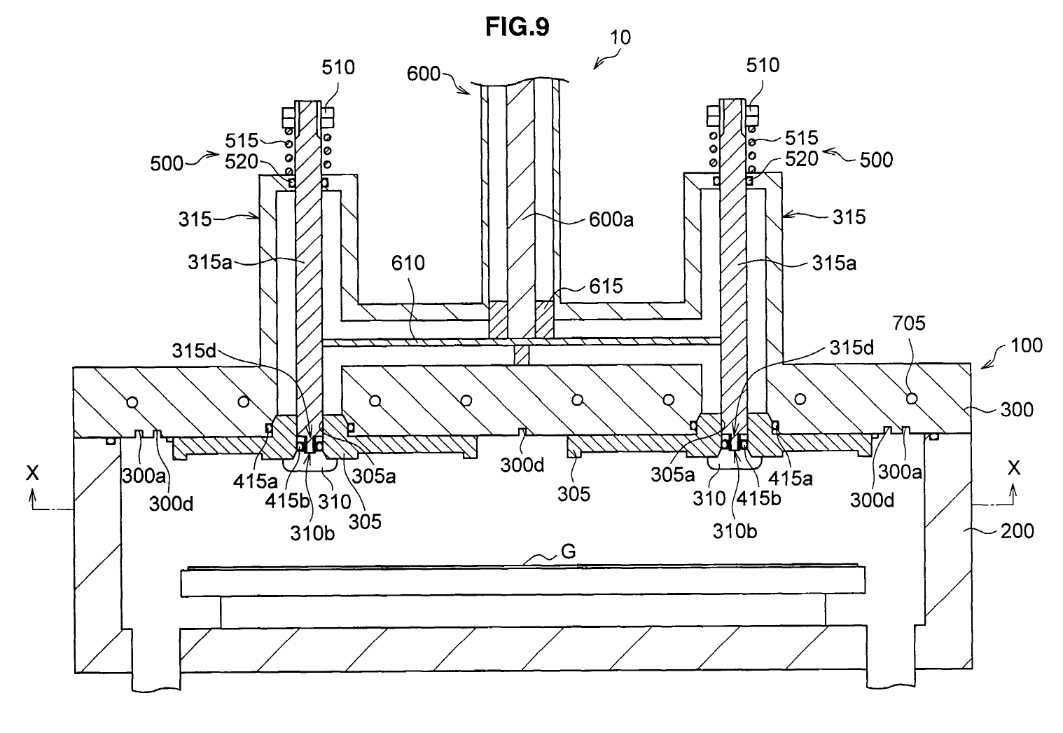

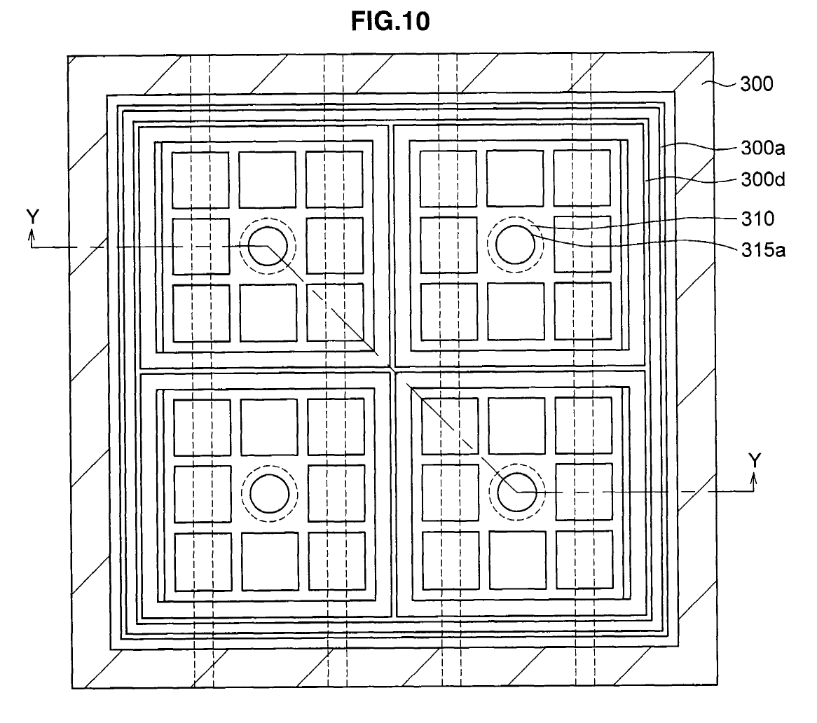

Note that although in the above embodiments, the inner and peripheral surfaces of the dielectric ring 410 are vacuum-sealed, the present invention is not limited thereto. For example, with reference to FIG. 9, the dielectric plate 305 and the dielectric ring 410 may be integrated. FIG. 10 shows a cross-sectional view taken along the line X-X in FIG. 9. FIG. 9 shows a cross-sectional view taken along the line Y-Y in FIG. 10.

The metal electrode 310 has a basal portion that extends into the through-hole 305a of the dielectric plate 305. The coaxial waveguide 315 and the metal electrode 310 are screwed and coupled to each other with a male screw 315d and a female screw 310b. The male screw 315d resides at the end of the coaxial waveguide 315. The female screw 310b resides at the basal portion of the metal electrode 310.

With reference to FIG. 3, which shows the dielectric ring 410 and the O-ring 415b, the O-ring 415b is first fitted in a space and then the dielectric ring 410 is attached. During attaching the dielectric ring 410, it may damage the O-ring 415b. In the structure in FIG. 9, the dielectric plate 305 tapers at the top. The dielectric plate 305 may thus be fitted more smoothly and the dielectric plate 305 may less damage the O-ring 415b during attaching the plate 305.

With reference to FIG. 9, the two O-rings 415a and 415b are provided on the inner and outer surfaces of the dielectric plate 305, respectively. Alternatively, the O-ring 415b may be provided between the inner surface of the dielectric plate 305 and the metal electrode 310, and the O-ring 415a may be provided between the peripheral surface of the dielectric plate 305 and the lid 300. This may also vacuum-seal the processing chamber U.

FIG. 10 shows the groove 300a and a plurality of grooves 300d. The groove 300a surrounds the whole dielectric plates 305. The grooves 300d surround the respective dielectric plates 305. The propagation of the conductor surface wave may thus be reduced.

In the above embodiments, the operations of the elements are related to each other. The operations may thus be replaced with a series of operations in consideration of the relations. Such a replacement may convert the embodiments of the plasma processing system to embodiments of a method of using a plasma processing system and a method of cleaning a plasma processing system.

### (Frequency Limitation)

The plasma processing system 10 according to each of the above embodiments may be used to output a microwave at a frequency of 1 GHz or less from the microwave source 900, thereby providing good plasma processing. The reason is described below.

The plasma CVD process uses a chemical reaction to deposit a thin film on the substrate surface. In the plasma CVD process, a film is adhered to both of the substrate surface and the processing chamber inner surface. The yield is decreased when the film adhered to the inner surface of the processing chamber is peeled off and deposited on the substrate. An impurity gas from the film adhered to the inner surface of the processing chamber may be incorporated in the thin film, thus degrading the film quality. For the high quality process, the inner surface of the chamber should be regularly cleaned.

The F radicals are often used to remove the silicon oxide film and the silicon nitride film. The F radicals may etch these films quickly. The F radicals may be generated by exciting a plasma in an F containing gas such as NF₃ or SF₆ to decompose the gas molecules. When a mixed gas including F and O is used to excite the plasma, the F and O recombine with electrons in the plasma, thus reducing the electron density of the plasma. Particularly, when a gas including F, the F having the highest electronegativity of all substances, is used to excite the plasma, the electron density is significantly reduced.

To prove this, the inventors generated a plasma and measured the electron density under the condition of a microwave at a frequency of 2.45 GHz, a microwave power density of 1.6 W cm⁻², and a pressure of 13.3 Pa. The results showed that the electron density in the Ar gas was 2.3×10¹² cm⁻³, while the density in the NF₃ gas was 6.3×10¹⁰ cm⁻³, which was less than one-tenth of that in the Ar gas.

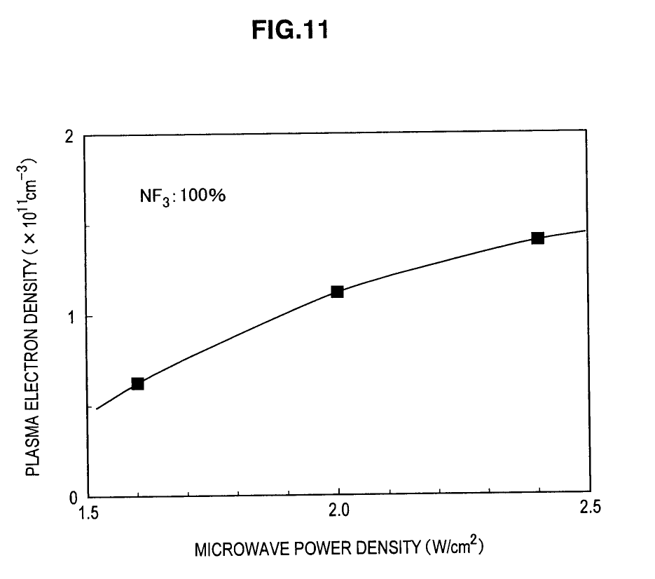

With reference to FIG. 11, as the microwave power density increases, the plasma electron density increases. Specifically, when the power density increases from 1.6 W/cm² to 2.4 W/cm², the plasma electron density increases from 6.3×10¹⁰ cm⁻³ to 1.4×10¹¹ cm⁻³.

When a microwave of 2.5 W/cm² or more is applied, it is more likely for the dielectric plate to be heated and cracked or the abnormal discharge to occur in the chamber, thereby leading to poor economy. It is thus practically difficult to provide an electron density of 1.4×10¹¹ cm⁻³ or more using the NF₃ gas. Specifically, to generate an uniform and stable plasma using an NF₃ gas having an extremely low electron density, the surface wave resonance density nₛ should be 1.4×10¹¹ cm⁻³ or less.

The surface wave resonance density nₛ represents the lowest electron density at which the surface wave may be propagated between the dielectric plate and the plasma. When the electron density is lower than the surface wave resonance density nₛ, the surface wave may not be propagated, thus exciting only an extremely nonuniform plasma. A cut-off density n_{c} is shown in the expression (1). The surface wave resonance density nₛ is proportional to the cut-off density n_{c} as shown in the expression (2).

n_{c}=ε₀ mₑω²/e² (1)

nₛ=n_{c} (1+εᵣ) (2)

where ε₀ is the dielectric constant of vacuum, mₑ is the electron's mass, ω is a microwave angle frequency, e is the elementary electric charge, and εᵣ is the specific inductive capacity of the dielectric plate.

The expressions (1) and (2) show that the surface wave resonance density nₛ is proportional to the square of the microwave frequency. This means that the low frequency may be selected to propagate the surface wave at a lower electron density and thus provide an uniform plasma. For example, when the microwave frequency is decreased to ½, even the electron density decreased to ¼ may provide an uniform plasma. The reduction of the microwave frequency is thus extremely effective to enlarge the process window.

At a frequency of 1 GHz, the surface wave resonance density nₛ equals the practical electron density of 1.4×10¹¹ cm⁻³ for the NF₃ gas. Specifically, when the microwave frequency is 1 GHz or less, any gas may be used to excite an uniform plasma having a practical power density.

Thus, a method of using a plasma processing system may include, for example: outputting an microwave at a frequency of 1 GHz or less from the microwave source 900 in the plasma processing system 10 in the above embodiments; transferring the electromagnetic wave from the microwave source 900 to a conductor rod (such as the inner conductor 315a), the conductor rod being raised by a device (such as the coil spring or the O-ring) to give the conductor rod a force directed away from a processing chamber, the conductor rod being coupled to a metal electrode to hold a dielectric plate; transferring the electromagnetic wave transferred through the conductor rod to the dielectric plate 305; and exciting a process gas introduced into the processing chamber 100 using the electromagnetic wave transmitted by the dielectric plate 305 and introduced into the processing chamber 100 and applying a desired plasma processing to a target object (such as the substrate G).

Particularly, a method of cleaning a plasma processing system may include, for example: outputting an microwave at a frequency of 1 GHz or less from the microwave source 900 in the plasma processing system 10 in the above embodiments; transferring the electromagnetic wave from the microwave source 900 to a conductor rod, the conductor rod being raised by a device to give the conductor rod a force directed away from a processing chamber, the conductor rod being coupled to a metal electrode to hold a dielectric plate; transferring the electromagnetic wave transferred through the conductor rod to the dielectric plate 305; and exciting a process gas introduced into the processing chamber 100 using the electromagnetic wave transmitted by the dielectric plate 305 and introduced into the processing chamber 100 and cleaning the plasma processing system.

The preface in “Microwave Plasma Technology,” by The Institute of Electrical Engineers of Japan & the Investigation Committee on Microwave Plasma, Ohmsha, Ltd. (Sep. 25, 2003) describes “the ‘microwave band’ refers to a frequency region of 300 MHz or more in the UHF band.” In the present specification, therefore, the frequency of the microwave refers to 300 MHz or more.

Although in the above embodiments, the microwave source 900 outputs a microwave at 915 MHz, other microwave sources that output microwaves at 896 MHz, 922 MHz, and 2.45 GHz may also be used.

Each member and the relation between the members in each embodiment will be briefly summarized below. The device to give the conductor rod a force directed away from the processing chamber may be a spring member. The device may also be a magnet. The spring member may include a first spring member outside the processing chamber. This may raise the conductor rod from outside the lid portion, thereby bringing the dielectric plate held by the metal electrode into close contact with the inner wall of the processing chamber. Another advantage is an easy maintenance including easy replacement of the first spring member.

The first spring member may then be either a coiled spring member or a plate spring member (such as a spring washer). The first spring member may also be either a metal spring or a ceramic spring.

The plasma processing system may also include a first dielectric member between the lid portion of the processing chamber and the conductor rod. The spring member may include a second spring member provided between the first dielectric member and the lid portion and also on the surface facing the dielectric plate (the surface closest to the dielectric material). This may also give the conductor rod a force directed away from the processing chamber, thereby bringing the dielectric plate held by the metal electrode into close contact with the inner wall of the processing chamber.

The second spring member may then be either an O-ring, a C-ring, a metal spring, or a ceramic spring. These members' elastic force may give a force to the conductor rod from the interior of the processing chamber, the force being directed away from the processing chamber.

The first dielectric member may be formed as a ring. The first dielectric member may have the conductor rod passing therethrough and be partially embedded in the lid portion of the processing chamber. A buffer member may be provided between the first dielectric member and the conductor rod and also on a surface facing outside the processing chamber. This may reduce the damage of the first dielectric member when the conductor rod is raised, the damage being caused by the local force applied to the contact portion of the first dielectric member with the conductor rod.

The buffer member may be made of Teflon (registered trademark). The member is preferably made of a somewhat soft material that has a buffering effect and low dielectric loss not to be overheated by the absorbed electromagnetic wave.

Between the first dielectric member and the conductor rod, a first sealing member may be provided to seal between the first dielectric member and the conductor rod. The second spring member and the first sealing member may include either an O-ring or a C-ring. This may vacuum-seal between the first dielectric member and the inner conductor of the conductor rod and between the first dielectric member and the processing chamber, thereby keeping the airtightness of the processing chamber.

The plasma processing system may also include a second dielectric member of a ring shape through which the conductor rod passes, a second sealing member, and a third sealing member. The second sealing member seals between the second dielectric member and the lid portion. The third sealing member seals between the conductor rod or the metal electrode and the second dielectric member.

This may vacuum-seal between the second dielectric member and the inner conductor of the conductor rod and between the second dielectric member and the lid portion, thereby keeping the airtightness of the processing chamber. The first dielectric member and the second dielectric member support the inner conductor of the conductor rod at two points. This may reduce the shaft swing of the conductor rod, thereby bringing the dielectric plate into closer contact with the inner wall of the processing chamber.

The second spring member and the first sealing member may be either an O-ring or an C-ring. The second sealing member and the third sealing member may also be either an O-ring or a C-ring.

The space between the first dielectric member and the second dielectric member may be maintained at a predetermined degree of vacuum. This may significantly decrease the amount of impurity gases passing through the second sealing member and the third sealing member, thereby increasing the cleanliness in the processing chamber.

The space between the first dielectric member and the second dielectric member may be filled with an inert gas. This may reduce the introduction of the atmosphere impurities into the processing chamber.

The first dielectric member and the second dielectric member may be made of quartz or alumina.

The dielectric plate may have an engaging portion between the dielectric plate and the lid portion. The engaging portion engages the dielectric plate and the lid portion. This may reduce the rotation of the dielectric plate around the axis of the conductor rod.

The engaging portion may be, for example, a convex member adjacent to the peripheral surface of the dielectric plate, the convex member securely fastened to the inner wall of the processing chamber.

The processing chamber and the conductor rod may each be made of metal. The processing chamber and the conductor rod may have a shorting portion at a portion where the conductor rod passes through the lid portion of the processing chamber. The shorting portion short-circuits the conductor rod and the processing chamber. The shorting portion may include, for example, a metal coil or metal brush or the like. This may electrically short-circuit the conductor rod and the processing chamber and increase the heat conduction near the shorting portion.

The processing chamber and the conductor rod may each be made of metal and include a shorting portion for short-circuiting the conductor rod and the processing chamber. The spring member may include a first spring member outside the shorting portion.

The conductor rod may engage with the shorting portion to be able to slide with respect to the lid portion of the processing chamber. This may reduce the cracks of the dielectric plate and the abnormal discharge generated in a gap between the dielectric plate and the inner wall of the processing chamber. The cracks and the gap are caused by the movement or extension of the conductor rod due to the spring's elastic force or heat stress.

During the process, the side of the dielectric plate may be in contact with the plasma. When, for example, the side of the dielectric plate is in contact with other members, the plasma may enter the gap between the members, causing the abnormal discharge. When, however, the side of the dielectric plate is in contact with the plasma, the abnormal discharge may not occur, thus generating a stable plasma.

The conductor rod may contain a cooling mechanism for cooling the conductor rod. This may reduce the overheating of the conductor rod and the metal electrode caused by the electromagnetic wave or the plasma.

The dielectric plate, the conductor rod, and the metal electrode may each be provided in a plurality. Each conductor rod may be coupled to one of the metal electrodes via a hole formed at a generally center of one of the dielectric plates.

This may allow for supply of a uniform electromagnetic wave into the processing chamber from the dielectric plates, thereby generating a uniform and stable plasma. It is advantageous that each of the dielectric plates may be supplied with the electromagnetic wave, thus providing a plasma processing system that has a high extensibility corresponding to a larger target object and facilitates the maintenance including the replacement of the dielectric plate.

The electromagnetic source may output an electromagnetic wave at a frequency of 1 GHz or less. The cut-off density may therefore be reduced and thus increase the process window, allowing for a variety of processes in one system.

The dielectric plate may be made of alumina.

The conductor rod is preferably made of copper. The copper has high thermal conductivity and high electrical conductivity. This may effectively release the heat applied to the conductor rod from the electromagnetic wave or the plasma and transfer the microwave efficiently.

Thus, the preferred embodiments of the present invention have been described with reference to the accompanying drawings, but it will be appreciated that the present invention is not limited to the disclosed embodiments. It should be understood by those skilled in the art that various modifications, combinations, sub-combinations and alterations may occur depending on design requirements and other factors insofar as they are within the scope of the appended claims or the equivalents thereof.

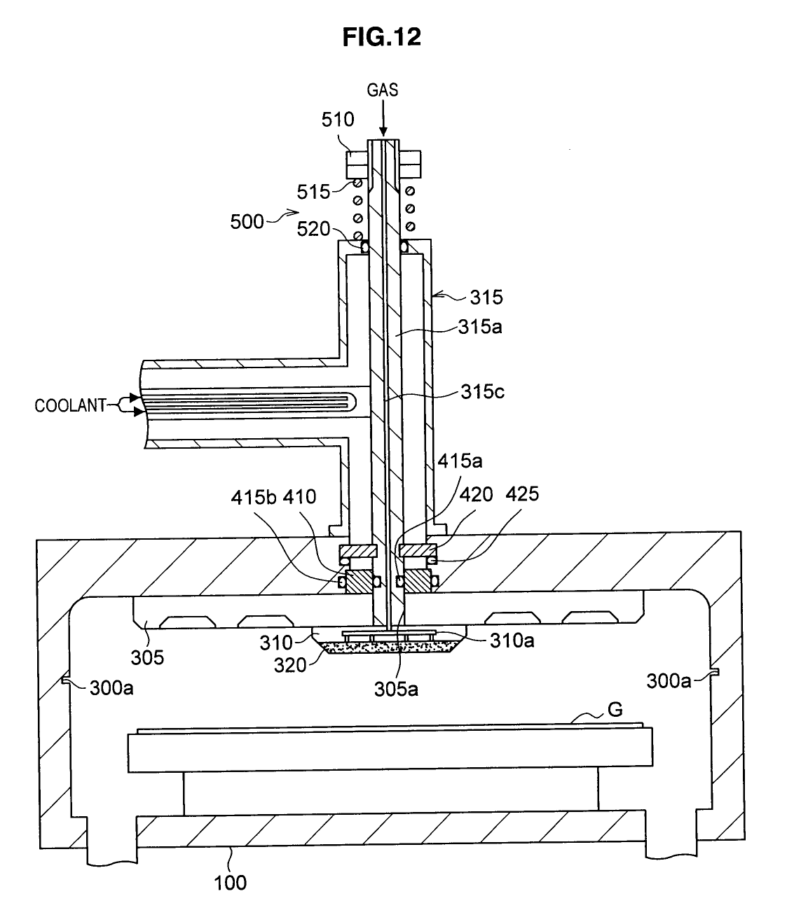

For example, the dielectric plate 305 in the plasma processing system according to the present invention may include a plurality of square dielectric plates. The dielectric plate 305 may also be a single large-area circular dielectric plate as shown in FIG. 12.

One metal electrode 310 coupled to one inner conductor 315a thus provides one dielectric plate 305 on the ceiling of the processing chamber 100. As in the plasma processing system having a plurality of dielectric plates 305, the side of the dielectric plate 305 is in contact with the plasma during the process.

This may thus avoid the abnormal discharge that occurs when the side of the dielectric plate 305 is in contact with other members (such as a metal frame) and the plasma enters the gap between the dielectric plate 305 and the members.

The plasma processing system according to the present invention may include both the first spring member and the second spring member or may include either of them or may include each in a plurality. The spring member may be other elements than the first spring member and the second spring member. The spring member may be, for example, a magnet.

The plasma processing system according to the present invention may also apply to processing of various substrates such as a large-area glass substrate, a circular silicon wafer, and a square silicon-on-insulator (SOI) substrate.

The plasma processing system according to the present invention may also apply to various plasma processes such as a deposition process, a propagation process, an etching process, and an ashing process.

What is claimed is:

1. A plasma processing system that excites a gas using an electromagnetic wave and applies a plasma process to a target object, the system comprising:
a processing chamber;
an electromagnetic source that outputs an electromagnetic wave;
a dielectric plate on the inner wall of the processing chamber, the dielectric plate transmitting the electromagnetic wave into the processing chamber;
a conductor rod adjacent to the dielectric plate, the conductor rod transferring the electromagnetic wave to the dielectric plate;
a metal electrode coupled to the conductor rod to hold the dielectric plate; and
a device to give the conductor rod a force directed away from the processing chamber.

2. The plasma processing system according to claim 1, wherein
the device to give the conductor rod a force directed away from the processing chamber is a spring member.

3. The plasma processing system according to claim 2, wherein
the spring member includes a first spring member provided outside a lid portion of the processing chamber.

4. The plasma processing system according to claim 3, wherein
the first spring member is either a coiled spring member or a plate spring member.

5. The plasma processing system according to claim 3, wherein
the first spring member is either a metal spring or a ceramic spring.

6. The plasma processing system according to claim 2, further comprising a first dielectric member between a lid portion of the processing chamber and the conductor rod, wherein
the spring member includes a second spring member between the first dielectric member and the lid portion of the processing chamber, the second spring member being provided on the surface facing the dielectric plate.

7. The plasma processing system according to claim 6, wherein
the second spring member is either an O-ring, a C-ring, a metal spring, or a ceramic spring.

8. The plasma processing system according to claim 6, wherein
the first dielectric member is formed as a ring, has the conductor rod passing therethrough, and is partially embedded in the lid portion of the processing chamber.

9. The plasma processing system according to claim 6, further comprising a buffer member provided between the first dielectric member and the conductor rod and also on a surface facing outside the processing chamber.

10. The plasma processing system according to claim 9, wherein
the buffer member is made of Teflon (registered trademark).

11. The plasma processing system according to claim 6 further comprising a first sealing member between the first dielectric member and the conductor rod for sealing between the first dielectric member and the conductor rod.

12. The plasma processing system according to claim 11, wherein
the second spring member and the first sealing member are each either an O-ring or an C-ring.

13. The plasma processing system according to claim 1, further comprising:
a second dielectric member of a ring shape through which the conductor rod passes;
a second sealing member for sealing between the second dielectric member and the lid portion of the processing chamber; and
a third sealing member for sealing between the second dielectric member and the conductor rod or the metal electrode.

14. The plasma processing system according to claim 13, wherein
the second sealing member and the third sealing member are each either an O-ring or a C-ring.

15. The plasma processing system according to claim 13, wherein
a space between the first dielectric member and the second dielectric member is maintained at a predetermined degree of vacuum.

16. The plasma processing system according to claim 13, wherein
an inert gas is filled in a space between the first dielectric member and the second dielectric member.

17. The plasma processing system according to claim 13, wherein
the first dielectric member and the second dielectric member are each made of either quartz or alumina.

18. The plasma processing system according to claim 1, further comprising an engaging portion between the dielectric plate and a lid portion of the processing chamber, the engaging portion being for engaging the dielectric plate and the lid portion of the processing chamber.

19. The plasma processing system according to claim 18, wherein
the engaging portion includes a convex member fastened to an inner wall of the processing chamber, the convex member being adjacent to a peripheral surface of the dielectric plate.

20. The plasma processing system according to claim 1, wherein
the processing chamber and the conductor rod are each made of metal, and
the system further comprises a shorting portion at a portion through which the conductor rod passes through a lid portion of the processing chamber, the shorting portion being for short-circuiting the conductor rod and the lid portion.

21. The plasma processing system according to claim 2, wherein
the lid portion and the conductor rod are each made of metal,
the system comprises a shorting portion for short-circuiting the conductor rod and the lid portion, and
the spring member includes a first spring member outside the shorting portion.

22. The plasma processing system according to claim 20, wherein
the conductor rod engages with the shorting portion to be able to slide with respect to the lid portion of the processing chamber.

23. The plasma processing system according to claim 20, wherein
the shorting portion is either a metal coil or a metal brush.

24. The plasma processing system according to claim 1, wherein
during the process, the side of the dielectric plate is in contact with the plasma.

25. The plasma processing system according to claim 1, wherein
the conductor rod contains a cooling mechanism for cooling the conductor rod.

26. The plasma processing system according to claim 1, wherein
the dielectric plate, the conductor rod, and the metal electrode are each provided in a plurality, and
each conductor rod is coupled to one of the metal electrodes via a hole formed at a substantially center of one of the dielectric plates.

27. The plasma processing system according to claim 1, wherein
the electromagnetic source outputs an electromagnetic wave at a frequency of 1 GHz or less.

28. The plasma processing system according to claim 1, wherein
the conductor rod is made of copper.

29. The plasma processing system according to claim 1, wherein
the dielectric plate is made of alumina.

30. A method of using a plasma processing system, the method comprising:
outputting an electromagnetic wave at a frequency of 1 GHz or less from an electromagnetic source;
transferring the electromagnetic wave to a conductor rod, the conductor rod being raised by a device to give the conductor rod a force directed away from a processing chamber, the conductor rod being coupled to a metal electrode to hold a dielectric plate;
transferring the electromagnetic wave transferred through the conductor rod to the dielectric plate adjacent to the conductor rod; and
exciting a process gas using the electromagnetic wave transmitted by the dielectric plate and introduced into the processing chamber and applying a desired plasma processing to a target object.

31. A method of cleaning a plasma processing system, the method comprising:
outputting an electromagnetic wave at a frequency of 1 GHz or less from an electromagnetic source;
transferring the electromagnetic wave to a conductor rod raised by a device to give the conductor rod a force directed away from a processing chamber, the conductor rod being coupled to a metal electrode to hold a dielectric plate;
transferring the electromagnetic wave transferred through the conductor rod to the dielectric plate adjacent to the conductor rod; and
exciting a cleaning gas using the electromagnetic wave transmitted by the dielectric plate and introduced into the processing chamber and cleaning the plasma processing system.
